(19) United States
(12) Patent Application Publication
(10) Pub. No.: US 2009/0211707 A1
(43) Pub. Date: Aug. 27, 2009

(54) APPARATUS FOR GAS DISTRIBUTION AND ITS APPLICATIONS

(75) Inventors: BENSON CHAO, HSINCHU (TW); TSAN-HUA HUANG, TAINAN CITY (TW)

Correspondence Address: ROSENBERG, KLEIN & LEE, 3458 ELLICOTT CENTER DRIVE-SUITE 101, ELLICOTT CITY, MD, 21043, US

(73) Assignee: HERMES SYSTEMS INC., HSINCHU (TW)

(21) Appl. No.: 12/035,689

(22) Filed: Feb. 22, 2008

(51) Int. Cl. H01L 21/306; C23C 16/44

(52) U.S. Cl. 156/345.34; 118/728; 118/715

(57) ABSTRACT

An apparatus for gas distribution includes a top dome-cover, a first gas distribution plate and a bottom plate bonded each other to deliver different gases onto substrates supporting by a susceptor. The first gas distribution plate is provided with a plurality of first island protrusions formed by intersecting a plurality of first channels and each first island protrusions has a bypass through hole so that different gases can be individually delivered via independent gas pathways formed by those through holes or those channels to prevent those different gases premix before processing on those substrates. Additionally, a fluid distribution plate disposed between the first gas distribution plate and the bottom plate may be adapted for heat dissipation.

### BACKGROUND OF THE INVENTION

1. Field of the Invention

The present invention relates to the field of semiconductor substrate processing system. More particularly, the present invention relates to a gas distribution apparatus which provides separate and uniform delivery of different gases onto substrates and inside a processing chamber.

2. Description of the Prior Art

In the fabrication of integrated circuit and compound semiconductor, processing chambers are generally employed to process semiconductor substrates. Those processing chambers include a gas distribution apparatus to effectuate depositions, epitaxy, etching, and so on.

The conventional chamber includes a casing with a cover, in which a heated susceptor is provided on which at least one substrate can be positioned. A central fluid inlet is provided for the supply of gases or liquids. The fluid outlet is then arranged on the periphery of the casing. Either central gas inlet nozzles, which permit the outflow of the gases from the center of gravity of the chamber via the substrates, or so-called showerheads are used in or on the cover. The showerheads are disposed directly above the substrate and spray the gas in the form of a shower through multiple small holes onto the substrates. The conventional metal-based showerheads adopt stainlesses steel or Al alloy material with welding-plates to separate different precursors and welding-tubing for passing through. This is a very complicated, costly and unreliable design. As the total welding points are over 13,000 for two or three precursors with water cooling and any welding defect may induce the leakage of precursors or water.

### SUMMARY OF THE INVENTION

The present invention generally provides a substrate processing chamber, apparatus, and associated methods, having a gas distribution apparatus that provides separate and uniform distribution of different gases and a high efficiency fluid cooling pathway within the processing chamber.

In one embodiment of the present invention, an apparatus for gas distribution in a processing chamber is provided. The apparatus for gas distribution in a processing chamber includes a top dome-cover having a first gas inlet and a second gas inlet with a first gas distribution plate disposed below the top dome-cover and a first gas buffer cavity formed between the top dome-cover and the first gas distribution plate. The first gas distribution plate includes: a plurality of first channels arranged on the first gas distribution plate at the opposite surface of the first gas buffer cavity and intersecting each other to define a plurality of first island protrusions; and a plurality of first bypass through holes arranged within the first island protrusions. And, a bottom plate disposed below the first gas distribution plate, wherein a second gas buffer cavity is formed at the first channels between the bottom plate and the first gas distribution plate; a plurality of first through holes are arranged on the bottom plate; and the first through holes are aligned at all the first bypass through hole and the second gas buffer cavity.

In another embodiment of the present invention, a semiconductor processing system is provided. The semiconductor processing system includes a processing chamber casing with a lid; a gas distribution apparatus disposed in the processing chamber and connected to the processing chamber for gas distribution. The apparatus for gas distribution in a processing chamber includes a top dome-cover having a first gas inlet and a second gas inlet for the gas communication; a first gas distribution plate disposed below the top dome-cover and a first gas buffer cavity formed between the top dome-cover and the first gas distribution plate. The first gas distribution plate includes: a plurality of first channels arranged on the first gas distribution plate at the opposite surface of the first gas buffer cavity and intersecting each other to define a plurality of first island protrusions; and a plurality of first bypass through holes arranged within the first island protrusions. And, a bottom plate disposed below the first gas distribution plate, wherein a second gas buffer cavity is formed at the first channels between the bottom plate and the first gas distribution plate; a plurality of first through holes are arranged on the bottom plate; and the first through holes are aligned at all the first bypass through hole and the second gas buffer cavity. And, a susceptor disposed below the gas distribution apparatus and adapted for supporting a plurality of substrates thereon.

In another embodiment of the present invention, a gas distribution showerhead is provided. The gas distribution showerhead includes a first gas distribution plate having a plurality of first channels arranged intersecting each other to define a plurality of first island protrusions thereon, wherein a plurality of first bypass through holes arranged within the first island protrusions. A fluid distribution plate disposed below the first gas distribution plate having a plurality of second channels arranged thereon at the bottom surface and intersecting each other to define a plurality of second island protrusions, wherein a plurality of second bypass through holes formed within the second island protrusions to align with each the first bypass through holes and connect with the first channels. A bottom plate disposed below the fluid distribution plate and having a plurality of first through holes thereon, wherein the first through holes are aligned with all the second bypass through holes. And, a cooling system having a fluid circulation from a fluid inlet to the second channels of the fluid distribution plate and to a fluid outlet to cool down the gas distribution showerhead itself.

Furthermore, the gas distribution apparatus can have more than one gas distribution plates stacked with each other to separately deliver more than two gases.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 shows a cross sectional view in accordance with one embodiment of the present invention;

FIG. 2 shows the assembled apparatus illustrating in accordance with one embodiment of the present invention;

FIG. 3A shows a cross sectional view in accordance with one embodiment of the present invention;

FIG. 3B shows a schematic bottom view of the fluid distribution plate in accordance with one embodiment of the present invention;

FIG. 4A shows a schematic diagram of the bottom plate in accordance with one embodiment of the present invention;

FIG. 4B shows a schematic diagram of the bottom plate in accordance with another embodiment of the present invention; and

FIG. 5 shows a schematic diagram in accordance with one embodiment of the present invention.

### DETAILED DESCRIPTION OF THE INVENTION

The present invention generally provides a substrate processing chamber having a gas distribution apparatus that provides separate and uniform distribution of at least two gases and a fluid cooling pathway provided within the processing chamber. The detailed explanation of the present invention is described as following. The described embodiments are presented for purposes of illustrations and description, and they are not intended to limit the scope of the present invention.

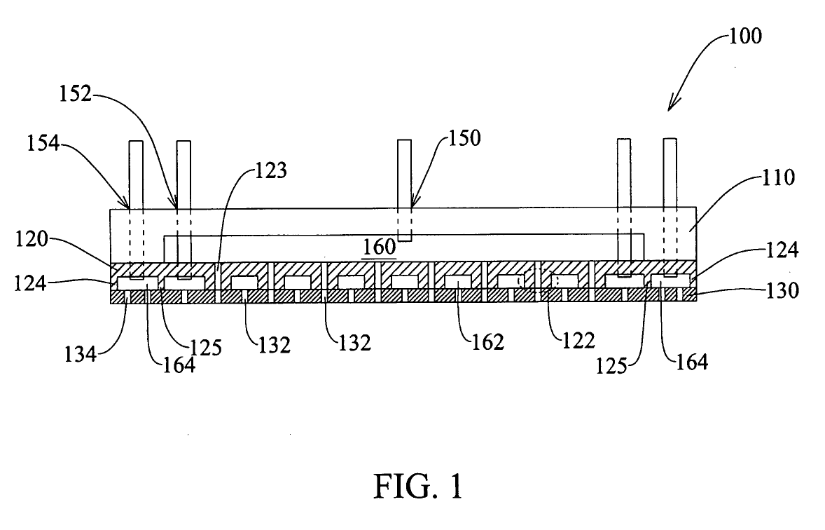

Firstly, refer to FIG. 1, FIG. 1 shows a cross sectional view of one embodiment of an apparatus for gas distribution in a processing chamber. The gas distribution apparatus 100 includes a top dome-cover 110 having a first gas inlet 150 and a second gas inlet 152 for the gas communication. A first gas distribution plate 120 is disposed below the top dome-cover 110 and a first gas buffer cavity 160 is formed between the top dome-cover 110 and the first gas distribution plate 120, wherein the first gas inlet 150 is in gas communication with the first gas buffer cavity 160. As shown in the figure, the first gas distribution plate 120 is a plate and includes a plurality of first channels arranged thereon at the opposite surface of the first gas buffer cavity 160 and intersecting each other to define a plurality of first island protrusions 122; and a plurality of first bypass through holes 123 arranged within the first island protrusions 122 in gas communication with the first gas buffer cavity 160. And, a bottom plate 130 is disposed below the first gas distribution plate 120, wherein a second gas buffer cavity 162 is formed at the first channels between the bottom plate 130 and the first gas distribution plate 120. The second gas inlet 152 is in gas communication with the second gas buffer cavity 162. A plurality of first through holes 132 are arranged on the bottom plate 130 and the first through holes 132 are aligned at all the first bypass through holes 123 of the first island protrusions 122 and the second gas buffer cavity 162. That is to say, the top dome-cover 110, the first gas distribution plate 120 and the bottom plate 130 are longitudinally gas communicated with each other. Hence, a first gas and a second gas may be injected into the gas inlet 150, 152 and then can be delivered by the first bypass through holes 123 and/or the first through holes 132 of the bottom plate 130 to eject into the processing chamber. Before those first gas and second gas are ejecting into the processing chamber, these two gases are separately and uniformly delivered in two different pathways so as to avoid those gases pre-mixing to react with each other.

Continuing the above description, in one embodiment, the gas distribution apparatus 100 for gas distribution may be profiled as a cylindrical shape and the top dome-cover 110, the first gas distribution plate 120 and the bottom plate 130 may be assembled by a bonding method, an o-ring method or a gasket method. Due to those first island protrusions 122 are formed by those first channels intersecting each other, those first island protrusions 122 and the first gas distribution plate 120 may be one-piece form and those first island protrusions 122 a re isolated to each other. Besides, those first island protrusions 122 may be profiled as a cube, a cylinder or a cone. In another embodiment, those first island protrusions 122 may be chamfered with an arc angle.

In one embodiment, as shown in FIG. 1, the gas distribution apparatus 100 abovementioned further includes a third gas inlet 154 arranged on the top dome-cover 110 for the gas communication. A third gas buffer cavity 164 formed at the edge region of the first gas distribution plate 120, wherein the third gas buffer cavity 164 is defined by two closed walls 124, 125; one wall 124 is arranged at the edge of the first gas distribution plate 120 and another wall 125 is surrounding those first channels and those first island protrusions 122; the walls 124, 125 are sealed with the bottom plate 130; and the third gas inlet 154 is in gas communication with the third gas buffer cavity 164. And, a plurality of second through holes 134 are formed at the edge region of the bottom plate 130 to connect with the third gas buffer cavity 164. In the embodiment, a third gas may be selectively provided to inject the third gas inlet 154. Due to those closed walls 124, 125, the second gas buffer cavity 162 and the third gas buffer cavity 164 are disconnected so that the third gas may go through the top dome-cover 110 and the third gas buffer cavity 164 to pass via the second through holes 134 to eject into the processing chamber. Hence, in this embodiment, three gases are also separately and uniformly delivered in self-reliant pathways.

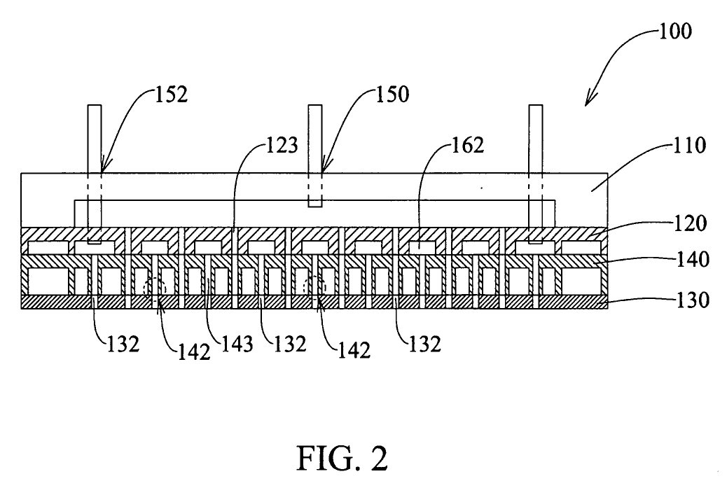

Referring to FIG. 2, FIG. 2 shows a cross sectional view of one embodiment of an apparatus for gas distribution in a processing chamber. In the embodiment, the gas distribution apparatus 100 further includes a fluid distribution plate 140 disposed below the first gas distribution plate 120. The fluid distribution plate 140 includes a plurality of second channels arranged on the fluid distribution plate 140 at the opposite surface of the second gas buffer cavity 162 and intersecting each other to define a plurality of second island protrusions 142. A plurality of second bypass through holes 143 are formed within the second island protrusions 142 of the fluid distribution plate 140 to connect with the second gas buffer cavity 162 or aligned with the first bypass through holes 123, wherein all the second bypass through holes 143 are aligned with the first through holes 132 of the bottom plate 130; and a fluid inlet and a fluid outlet (not shown in the figures) are formed on the fluid distribution plate 140 to let the fluid circulation from the fluid inlet to those second channels of the fluid distribution plate 140 and to the fluid outlet to cool down the gas distribution apparatus 100.

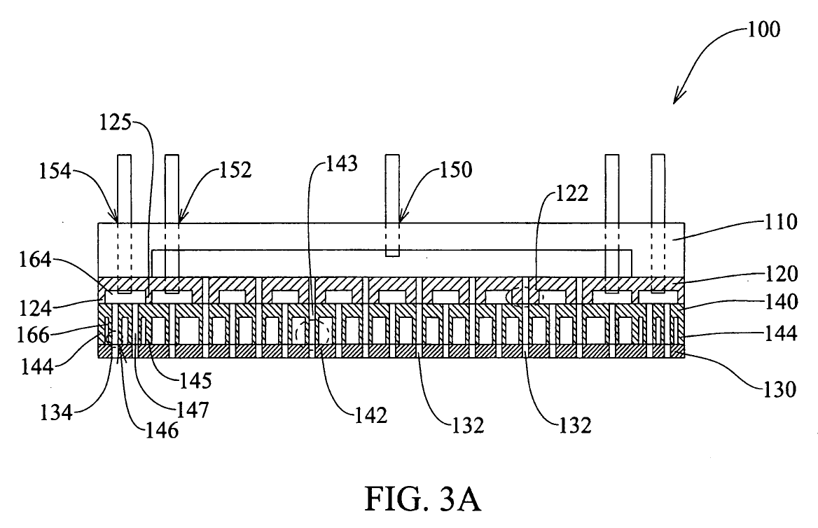

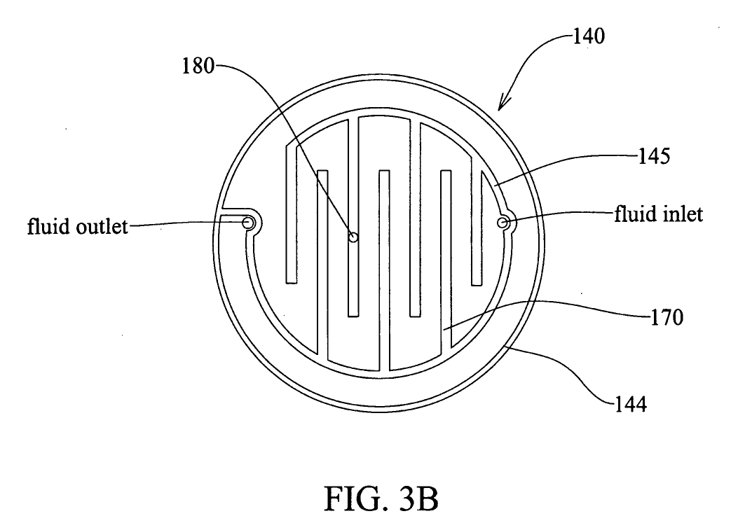

Continuously, refer to FIG. 3A and FIG. 3B, in one embodiment, the fluid distribution plate 140 further includes a fluid buffer cavity 166 formed at the edge region of the fluid distribution plate 140, wherein the fluid buffer cavity 166 is defined by two walls 144, 145; one wall 144 is arranged at the edge of the fluid distribution plate 140 and another wall 145-is surrounding the second channels and the second island protrusions 142 of the fluid distribution plate 140; one end of the another wall 145 is jointed with the edge wall 144 and another end is configured an opening with the end; and referring to FIG. 3B, a plurality of separation walls 170 arranged on the fluid distribution plate 140 to configured a winding loop within the second channels of the fluid distribution plate 140, wherein the fluid inlet is arranged within the region of the another wall 145 and the fluid outlet is arranged outside the another wall 145 and at the end. Wherein the design of the separation walls 170 and the second island protrusions 142 may let the fluid uniformly flow through the fluid distribution plate 140 to optimize the heat dissipation effect. In one embodiment, as shown in the figure, the possible fluid circulation pathway may begin from the fluid inlet and through the winding loop formed by the separation walls 170 to the region between two walls 144, 145 and to the fluid outlet. It is understood that the reverse-directional fluid circulation may also be included in the scope of the present invention. Besides, refer to FIG. 3B, if there is any view port 180 on the gas distribution apparatus 100, the view port 180 may penetrate through the gas distribution apparatus 100 and pierce through the separation walls 170 for observing the susceptor placed below the gas distribution apparatus 100, wherein the view port 180 formed on the separation walls 170 can keep the cooling fluid flow smoothly. In one embodiment, the second island protrusions 142 may be chamfered with an arc angle as the abovementioned embodiment to let the fluid flow through those second island protrusions 142 smoothly.

In another embodiment, refer to FIG. 3A, the gas distribution apparatus 100 provided with the fluid distribution 140 may further includes a third gas inlet 154 arranged on the top dome-cover 110 for the gas communication. A third gas buffer cavity 164 formed at the edge region of the first gas distribution plate 120, wherein the third gas buffer cavity 164 is defined by two closed walls 124, 125; one wall 124 is arranged at the edge of the first gas distribution plate 120 and another wall 125 is surrounding the first channels and the first island protrusions 122; the walls 124, 125 are sealed with the fluid distribution plate 140; and the third gas inlet 154 is connecting with the third gas buffer cavity 164. And, a plurality of third island protrusions 146 arranged at the edge region of the fluid distribution plate 140, wherein the third island protrusions 146 of the fluid distribution plate 140 are sealed with the surface of the bottom plate 130; a plurality of third bypass through holes 147 formed within the third island protrusions 146 of the fluid distribution plate 140, wherein a portion of the first through holes 132 of the bottom plate 130 are aligned all the third bypass through holes 147. By the design, the third gas may be delivered from the third gas inlet 154 and through the third gas buffer cavity 164 and the third bypass through holes 147 to the first through holes 132 of the bottom plate 130 to eject into the processing chamber.

Continuously, in the abovementioned embodiments, the top dome-cover 110, the first gas distribution plate 120, the fluid distribution plate 140 and the bottom plate 130 may be made of metal or ceramic material. In one embodiment, the numbers of the second island protrusions 142 of the fluid distribution plate 140 which are passed by the gases injected from the first gas inlet 150 are identical to those passed by the gases injected from the second gas inlet 152. Further, the size of the first island protrusions 122 of the first gas distribution plate 120 differs from the second island protrusion 142 of the fluid distribution plate 140. Furthermore, the arrangement density of the first island protrusions 122 of the first gas distribution plate 120 and the arrangement density of the second island protrusions 142 of the fluid distribution plate 140 may also be different.

Furthermore, in the last embodiment, the fluid distribution plate 140 may further include a fluid buffer cavity 166 and a plurality of separation walls 170, wherein those third island protrusions 146 are arranged between the wall 144 and another wall 145. The structure of the wall 144, 145, the fluid buffer cavity 166 and the separation walls 170 have been described above (refer to FIG. 3A and FIG. 3B), so there is no unnecessary detail here. In this embodiment, refer to FIG. 3A, the third gas may go through the top dome-cover 110 and the third gas buffer cavity 164 to pass via the third bypass through holes 147 and the second through holes 134 to eject into the processing chamber. Besides, the design of the fluid pathway is identical with forementioned embodiment, so there is no unnecessary detail here. Hence, the gases are also separately and uniformly delivered in self-reliant pathways and the unique fluid cooling path may improve the heat issue.

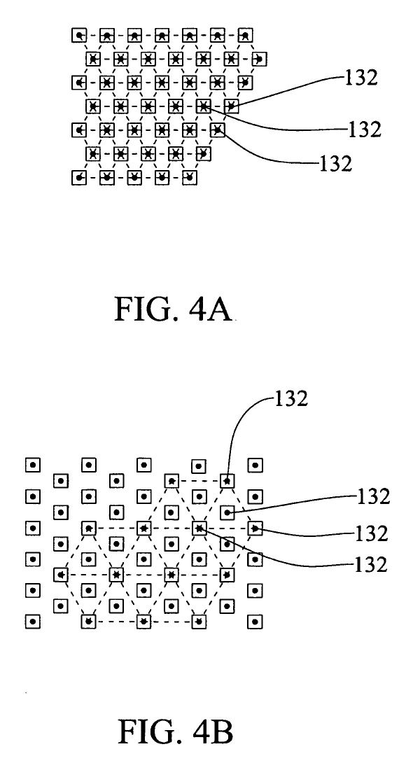

Furthermore, the repetition of the above structure can form more than two different gas distributions. In one embodiment, the gas distribution apparatus can have more than one gas distribution plates stacked with each other to separately deliver more than two gases, and each gas distribution plate can be utilized to separately deliver at least one more gas. Hence, more than two gases can be delivered in the gas distribution apparatus by utilizing more than one gas distribution plates. Additionally, each gas can be separately delivered from separate pathways, for example different bypass through holes on different gas distribution plates, to the first through holes of the bottom plate, and the arrangement of the first through holes can be changed according to the number of the gases. In the embodiment, refer to FIG. 4A, if there are three gases for gas distribution, the first through holes 132 of the bottom plate can be arranged in array to form a plurality of regular triangles, and the first through holes 132 located at the vertices of the smallest unit of those regular triangles are respectively to pass through three different gases. In another embodiment, as shown in FIG. 4B, if there are four gases for gas distribution, the first through holes 132 can be arranged in array to form a plurality of regular triangles, wherein the first through holes 132 located at the vertices and the center of the smallest unit of those regular triangles are respectively to pass through four different gases.

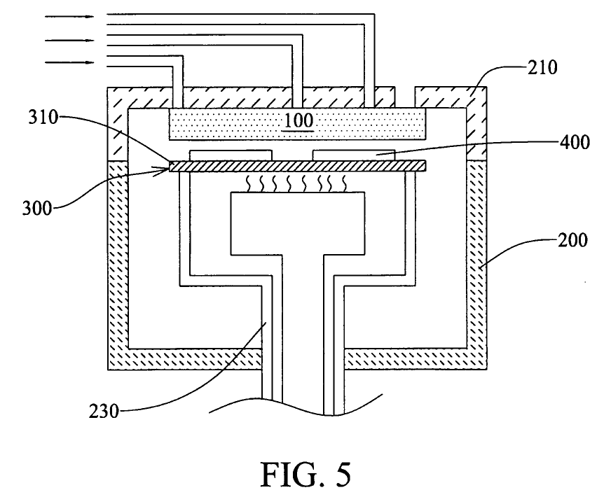

FIG. 5 shows a schematic diagram of one embodiment of a semiconductor processing system according to the present invention. In the embodiment, the gas distribution apparatus 100 for gas distribution abovementioned is applied on a semiconductor processing system. As shown in the figure, the semiconductor processing system includes a processing chamber 200 casing with a lid 210; a gas distribution apparatus 100 disposed in the processing chamber 200 and connected to the processing chamber 200 for gas distribution, and a susceptor 300 disposed below the gas distribution apparatus 100 and adapted for supporting a plurality of substrates 400, such as wafers, thereon, wherein the susceptor 300 is profiled as a thin plate. In this embodiment, two or three gases may be injected from the gas pipe (as the arrow shown in the figure) and be delivered by separate pathways of the gas distribution apparatus 100 then onto substrates 400. The gas distribution apparatus 100 has been described above, so there is no unnecessary detail here. Moreover, in one embodiment, the susceptor 300 is made of high thermal conduction material, like Nitride-based or Carbon-based ceramics to get low thermal mass. In one embodiment, the susceptor 300 is locked to a rotator 230 with pins. And, as shown in the figure, a plurality of ear-rings 310 protruded from the susceptor 300 for robot automation. Besides, in another embodiment, the susceptor 300 is placed on the rotator 230 for rotating. The susceptor 300 may have a cut-out opening (not shown in the figure) at the periphery thereof for automation, wherein the cut-out opening may be locked from inside of the rotator 230 to prevent turbulence flow during processing. Furthermore, in one embodiment, without the ear-ring 310 or the cur-out design, the diameter of the rotator 230 under the susceptor 300 may be 1-5 mm smaller for robot pickup design.

According to the above description, one feature of the present invention is applying an apparatus for gas distribution in the processing chamber to provide the high efficiency of cooling and high uniformity of precursor-gases distribution for semiconductor. And, the thickness or the material of each plate of the gas distribution apparatus may be varied according to different design. More, in the semiconductor processing system, a thin-plated susceptor made of high thermal conductivity, low thermal mass and high density material is provided to quick temperature ramp-up/down for processing equipment and automation handling.

To sum up the foregoing descriptions, the present invention provides a substrate processing chamber, apparatus, and associated methods, having a gas distribution apparatus that provides separate and uniform distribution of different gases and a high efficiency fluid cooling pathway within the processing chamber.

The foregoing descriptions of specific embodiments of the present invention have been presented for purposes of illustrations and description. They are not intended to be exclusive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to particular use contemplated. It is intended that the scope of the invention be defined by the claims appended hereto and their equivalents.

What is claimed is:

1. An apparatus for gas distribution in a processing chamber, comprising:
a top dome-cover having a first gas inlet and a second gas inlet for the gas communication;
a first gas distribution plate disposed below said top dome-cover and a first gas buffer cavity formed between said top dome-cover and said first gas distribution plate, said first gas distribution plate comprises:
a plurality of first channels arranged on said first gas distribution plate at the opposite surface of said first gas buffer cavity and intersecting each other to define a plurality of first island protrusions; and
a plurality of first bypass through holes arranged within said first island protrusions; and
a bottom plate disposed below said first gas distribution plate, wherein
a second gas buffer cavity is formed at said first channels between said bottom plate and said first gas distribution plate;
a plurality of first through holes are arranged on said bottom plate; and
said first through holes are aligned at all said first bypass through holes and said second gas buffer cavity.

2. The apparatus for gas distribution according to claim 1, further comprising:
a third gas inlet arranged on said top dome-cover for the gas communication;
a third gas buffer cavity formed at the edge region of said first gas distribution plate, wherein said third gas buffer cavity is defined by two closed walls; one wall is arranged at the edge of said first gas distribution plate and another is surrounding said first channels and said first island protrusions; said walls are sealed with said bottom plate; and said third gas inlet in gas communication with said third gas buffer cavity; and
a plurality of second through holes formed at the edge region of said bottom plate to connect with said third gas buffer cavity.

3. The apparatus for gas distribution according to claim 1, further comprising a fluid distribution plate disposed below said first gas distribution plate, said fluid distribution plate comprises:
a plurality of second channels arranged on said fluid distribution plate at the opposite surface of said second gas buffer cavity and intersecting each other to define a plurality of second island protrusions;
a plurality of second bypass through holes formed within said second island protrusions of said fluid distribution plate to connect with said second gas buffer cavity or aligned with said first bypass through holes, wherein all said second bypass through holes are aligned with said first through holes of said bottom plate; and
a fluid inlet and a fluid outlet arranged on said fluid distribution plate to let a fluid circulation from said fluid inlet to said second channels of said fluid distribution plate and to said fluid outlet to cool down said apparatus.

4. The apparatus for gas distribution according to claim 3, wherein said fluid distribution plate further comprises:
a fluid buffer cavity formed at the edge region of said fluid distribution plate, wherein said fluid buffer cavity is defined by two walls; one wall is arranged at the edge of said fluid distribution plate and another is surrounding said second channels and said second island protrusions of said fluid distribution plate; one end of said another wall is jointed with said edge wall and another end is configured an opening with said end; and a plurality of separation walls arranged on said fluid distribution plate to configured a winding loop within said second channels of said fluid distribution plate, wherein said fluid inlet is arranged within the region of said another wall and said fluid outlet is arranged outside said another wall and at said end.

5. The apparatus for gas distribution according to claim 4, wherein said fluid circulation begins from said fluid inlet and through said winding loop formed by said separation walls to the region between two said walls and to said fluid outlet.

6. The apparatus for gas distribution according to claim 3, further comprising:
a third gas inlet arranged on said top dome-cover for the gas communication;
a third gas buffer cavity arranged at the edge region of said first gas distribution plate, wherein said third gas buffer cavity is defined by two closed walls; one wall is arranged at the edge of said first gas distribution plate and another is surrounding said first channels and said first island protrusions; said walls are sealed with said fluid distribution plate; and said third gas inlet is connecting with said third gas buffer cavity; and
a plurality of third island protrusions arranged at the edge region of said fluid distribution plate, wherein said third island protrusions of said fluid distribution plate are sealed with the surface of said bottom plate;
a plurality of third bypass through holes arranged with said third island protrusions of said fluid distribution plate, wherein a portion of said first through holes of said bottom plate are aligned with all said third bypass through holes.

7. The apparatus for gas distribution according to claim 6, wherein said fluid distribution plate further comprises:
a fluid buffer cavity arranged at the edge region of said fluid distribution plate, wherein said fluid buffer cavity is defined by two walls; one wall is arranged at the edge of said fluid distribution plate and another is surrounding said second channels and said second island protrusions of said fluid distribution plate, wherein said third island protrusions of said fluid distribution plate are arranged between said wall and said another wall of said fluid distribution plate; one end of said another wall is jointed with said edge wall and another end is configured an opening with said end; and a plurality of separation walls arranged on said fluid distribution plate to configured a winding loop within said second channels of said fluid distribution plate, wherein said fluid inlet is arranged within the region of said another wall and said fluid outlet is arranged outside said another wall and at said end.

8. The apparatus for gas distribution according to claim 7, wherein said fluid circulation begins from said fluid inlet and through said winding loop formed by said separation walls to the region between two said walls and to said fluid outlet.

9. The apparatus for gas distribution according to claim 3, wherein the numbers of the second island protrusions of said fluid distribution plate which are passed by the gases injected from said first gas inlet are identical to those passed by the gases injected from said second gas inlet.

10. The apparatus for gas distribution according to claim 3, wherein the size of said first island protrusions of said first gas distribution plate can differ from or equal to the size of said second island protrusions of said fluid distribution plate.

11. The apparatus for gas distribution according to claim 3, wherein the arrangement density of said first island protrusions of said first gas distribution plate and the arrangement density of said second island protrusions of said fluid distribution plate is different.

12. The apparatus for gas distribution according to claim 3, wherein said fluid distribution plate is made of metal or ceramic material.

13. The apparatus for gas distribution according to claim 1, wherein said top dome-cover, said first gas distribution plate or said bottom plate are made of metal or ceramic material.

14. The apparatus for gas distribution according to claim 1, wherein said first island protrusions and said first gas distribution plate are one-piece form.

15. The apparatus for gas distribution according to claim 1, wherein said top dome-cover, said first gas distribution plate and said bottom plate are longitudinally gas communicated with each other.

16. The apparatus for gas distribution according to claim 1, wherein said first island protrusions are profiled as a cube, a cylinder or a cone.

17. The apparatus for gas distribution according to claim 1, wherein said first island protrusions are chamfered with an arc angle.

18. The apparatus for gas distribution according to claim 1, wherein the assembly method of said top dome-cover, said first gas distribution plate and said bottom plate is selected from the group consisting of the bonding method, the o-ring method and the gasket method.

19. The apparatus for gas distribution according to claim 1, wherein said first gas inlet is in gas communication with said first gas buffer cavity.

20. The apparatus for gas distribution according to claim 1, wherein said first bypass through holes are in gas communication with said first gas buffer cavity.

21. The apparatus for gas distribution according to claim 1, wherein said second gas inlet is in gas communication with said second gas buffer cavity.

22. A semiconductor processing system, comprising:
a processing chamber casing with a lid;
a gas distribution apparatus disposed in said processing chamber and connected to said processing chamber utilized for gas distribution, said gas distribution apparatus comprising:
a top dome-cover having a first gas inlet and a second gas inlet for the gas communication;
a first gas distribution plate disposed below said top dome-cover and a first gas buffer cavity formed between said top dome-cover and said first gas distribution plate, said first gas distribution plate comprises:
a plurality of first channels arranged on said first gas distribution plate at the opposite surface of said first gas buffer cavity and intersecting each other to define a plurality of first island protrusions; and
a plurality of first bypass through holes arranged within said first island protrusions; and
a bottom plate disposed below said first gas distribution plate, wherein
a second gas buffer cavity is formed at said first channels between said bottom plate and said first gas distribution plate;
a plurality of first through holes are arranged on said bottom plate; and
said first through holes are aligned at all said first bypass through holes and said second gas buffer cavity; and
a susceptor disposed below said gas distribution apparatus and adapted for supporting a plurality of substrates thereon.

23. The semiconductor processing system according to claim 22, wherein said gas distribution apparatus further comprises:
a third gas inlet arranged on said top dome-cover for the gas communication;
a third gas buffer cavity formed at the edge region of said first gas distribution plate, wherein said third gas buffer cavity is defined by two closed walls; one wall is arranged at the edge of said first gas distribution plate and another is surrounding said first channels and said first island protrusions; said walls are sealed with said bottom plate; and said third gas inlet in gas communication with said third gas buffer cavity; and
a plurality of second through holes formed at the edge region of said bottom plate to connect with said third gas buffer cavity.

24. The semiconductor processing system according to claim 22, wherein said gas distribution apparatus further comprises a fluid distribution plate disposed below said first gas distribution plate, said fluid distribution plate comprises:
a plurality of second channels arranged on said fluid distribution plate at the opposite surface of said second gas buffer cavity and intersecting each other to define a plurality of second island protrusions;
a plurality of second bypass through holes formed within said second island protrusions of said fluid distribution plate to connect with said second gas buffer cavity or aligned with each said first bypass through holes, wherein all said second bypass through holes are aligned with said first through holes of said bottom plate; and
a fluid inlet and a fluid outlet arranged on said fluid distribution plate to let the fluid circulation from said fluid inlet to said second channels of said fluid distribution plate and to said fluid outlet to cool down said gas distribution apparatus.

25. The semiconductor processing system according to claim 24, wherein said fluid distribution plate further comprises:
a fluid buffer cavity formed at the edge region of said fluid distribution plate, wherein said fluid buffer cavity is defined by two walls; one wall is arranged at the edge of said fluid distribution plate and another is surrounding said second channels and said second island protrusions of said fluid distribution plate; one end of said another wall is jointed with said edge wall and another end is configured an opening with said end; and a plurality of separation walls arranged on said fluid distribution plate to configured a winding loop within said second channels of said fluid distribution plate, wherein said fluid inlet is arranged within the region of said another wall and said fluid outlet is arranged outside said another wall and at said end.

26. The semiconductor processing system according to claim 24, wherein said gas distribution apparatus further comprises:
a third gas inlet arranged on said top dome-cover for the gas communication;
a third gas buffer cavity arranged at the edge region of said first gas distribution plate, wherein said third gas buffer cavity is defined by two closed walls; one wall is arranged at the edge of said first gas distribution plate and another is surrounding said first channels and said first island protrusions; said walls are sealed with said fluid distribution plate; and said third gas inlet is connecting with said third gas buffer cavity;
a plurality of third island protrusions arranged at the edge region of said fluid distribution plate, wherein said third island protrusions of said fluid distribution plate are sealed with the surface of said bottom plate; and
a plurality of third bypass through holes arranged with said third island protrusions of said fluid distribution plate, wherein a portion of said first through holes of said bottom plate are aligned all said third bypass through holes.

27. The semiconductor processing system according to claim 26, wherein said fluid distribution plate further comprises:
a fluid buffer cavity arranged at the edge region of said fluid distribution plate, wherein said fluid buffer cavity is defined by two walls; one wall is arranged at the edge of said fluid distribution plate and another is surrounding said second channels and said second island protrusions of said fluid distribution plate, wherein said third island protrusions of said fluid distribution plate are arranged between said wall and said another wall of said fluid distribution plate; one end of said another wall is jointed with said edge wall and another end is configured an opening with said end; and a plurality of separation walls arranged on said fluid distribution plate to configured a winding loop within said second channels of said fluid distribution plate, wherein said fluid inlet is arranged within the region of said another wall and said fluid outlet is arranged outside said another wall and at said end.

28. The semiconductor processing system according to claim 24, wherein the numbers of said first island protrusions of said fluid distribution plate which are passed by the gases injected from said first gas inlet are identical to those passed by the gases injected from said second gas inlet.

29. The semiconductor processing system according to claim 24, wherein the size of said first island protrusions of said first gas distribution plate differs from the size of said second island protrusions of said fluid distribution plate.

30. The semiconductor processing system according to claim 24, wherein the arrangement density of said first island protrusions of said first gas distribution plate and the arrangement density of said second island protrusions of said fluid distribution plate is different.

31. The semiconductor processing system according to claim 24, wherein said fluid distribution plate is made of metal or ceramic material.

32. The semiconductor processing system according to claim 22, wherein said top dome-cover, said first gas distribution plate or said bottom plate are made of metal or ceramic material.

33. The semiconductor processing system according to claim 22, wherein said first island protrusions and said gas distributing plate are one-piece form.

34. The semiconductor processing system according to claim 22, wherein said top dome-cover, said first gas distribution plate and said bottom plate are longitudinally gas communicated with each other.

35. The semiconductor processing system according to claim 22, wherein said first island protrusions are profiled as a cube, a cylinder or a cone.

36. The semiconductor processing system according to claim 22, wherein said first island protrusions are chamfered with an arc angle.

37. The semiconductor processing system according to claim 22, wherein the assembly method of said top dome-cover, said first gas distribution plate and said bottom plate is selected from the group consisting of the bonding method, the o-ring method and the gasket method.

38. The semiconductor processing system according to claim 22, wherein said susceptor is made of high thermal conduction material.

39. The semiconductor processing system according to claim 38, wherein said susceptor is made of Nitride-based or Carbon-based ceramics.

40. The semiconductor processing system according to claim 22, wherein said susceptor has a plurality of ear-rings protruded therefrom for robot automation.

41. The semiconductor processing system according to claim 22, wherein said susceptor is placed on a rotator for rotating.

42. The semiconductor processing system according to claim 41, wherein said susceptor has a cut-out opening at the periphery thereof for automation.

43. The semiconductor processing system according to claim 22, wherein said first gas inlet is in gas communication with said first gas buffer cavity.

44. The semiconductor processing system according to claim 22, wherein said first bypass through holes are in gas communication with said first gas buffer cavity.

45. The semiconductor processing system according to claim 22, wherein said second gas inlet is in gas communication with said second gas buffer cavity.

46. A gas distribution showerhead comprising:
a first gas distribution plate having a plurality of first channels arranged intersecting each other to define a plurality of first island protrusions thereon, wherein a plurality of first bypass through holes arranged within said first island protrusions;
a fluid distribution plate disposed below said first gas distribution plate having a plurality of second channels arranged thereon at the bottom surface and intersecting each other to define a plurality of second island protrusions, wherein a plurality of second bypass through holes formed within said second island protrusions to align with each said first bypass through holes and connect with said first channels;
a bottom plate disposed below said fluid distribution plate and having a plurality of first through holes thereon, wherein said first through holes are aligned with all said second bypass through hole; and
a cooling system having a fluid circulating from a fluid inlet to said second channels of said fluid distribution plate and to a fluid outlet to cool down said gas distribution showerhead.

47. The gas distribution showerhead according to claim 46, further comprising a second gas distribution plate arranged between said first gas distribution plate and said fluid distribution plate, wherein
said second gas distribution plate has a plurality of third channels arranged intersecting each other to define a plurality of third island protrusions thereon; and
a plurality of third bypass through holes arranged within said third island protrusions to align said first bypass through holes and a portion of said second bypass through holes.

48. The gas distribution showerhead according to claim 47, wherein said portion of said second bypass through hole connects with said third channels.

49. The gas distribution showerhead according to claim 47, further comprising a third gas distribution plate arranged between said second gas distribution plate and said fluid distribution plate, wherein
said third gas distribution plate has a plurality of fourth channels arranged intersecting each other to define a plurality of fourth island protrusions thereon; and
a plurality of fourth bypass through holes arranged within said fourth island protrusions to align said third bypass through holes and a portion of said second bypass through holes.

50. The gas distribution showerhead according to claim 49, wherein said portion of said second bypass through hole connects with said fourth channels.

51. The gas distribution showerhead according to claim 49, wherein said first through holes are arranged in array to form a plurality of regular triangles, wherein said first through holes located at the vertices and the center of the smallest unit of said regular triangles are respectively to pass through different gases.

52. The gas distribution showerhead according to claim 47, wherein said first through holes are arranged in array to form a plurality of regular triangles, and said first through holes located at the vertices of the smallest unit of said regular triangles are respectively to pass through different gases.

53. The gas distribution showerhead according to claim 49, wherein said first gas distribution plate has a gas buffer cavity formed at the edge region, wherein said gas buffer cavity is defined by two closed walls; one wall is arranged at the edge of said first gas distribution plate and another is surrounding said first channels and said first island protrusions; said walls are sealed with said bottom plate; and a plurality of second through holes formed at the edge region of said bottom plate to connect with said gas buffer cavity.
